(19) United States
(12) Patent Application Publication
(10) Pub. No.: US 2026/0206500 A1
(43) Pub. Date: Jul. 16, 2026

(54) SUBSTRATE PROCESSING METHOD OR SYSTEM FOR THE METHOD, AND A SEMICONDUCTOR DEVICE PRODUCTION METHOD

(71) Applicants: SAMSUNG ELECTRONICS CO., LTD., Suwon-si (KR); POSTECH RESEARCH AND BUSINESS DEVELOPMENT FOUNDATION, Pohang-si (KR)

(72) Inventors: Myong Jong KWON, Suwon-si (KR); Byung Ha PARK, Suwon-si (KR); Suk Gyu HAHM, Suwon-si (KR); Kyu Wook IHM, Pohang-si (KR)

(21) Appl. No.: 19/446,145

(22) Filed: Jan. 12, 2026

(30) Foreign Application Priority Data
Jan. 13, 2025 (KR) 10-2025-0005069

(51) Int. Cl. H10P 14/20; C23C 16/40; C23C 16/455

(52) U.S. Cl. CPC H10P 14/271; C23C 16/405; C23C 16/45553

(57) ABSTRACT

A method of processing a substrate and a substrate processing system. The substrate treatment method includes evaporating, under a pressure below atmospheric pressure, an organic inhibitor compound from a porous medium impregnated with the organic inhibitor compound to provide a evaporated organic inhibitor compound; and selectively depositing the evaporated organic inhibitor compound under a first pressure on a first region of a substrate in a first chamber including the substrate, for a predetermined time to form a self-assembled monolayer including the organic inhibitor compound on the first region of the substrate.

### CROSS-REFERENCE TO RELATED APPLICATION

This application claims priority to Korean Patent Application No. 10-2025-0005069, filed on Jan. 13, 2025, in the Korean Intellectual Property Office, and all the benefits accruing therefrom under 35 U.S.C. § 119, the content of which in its entirety is incorporated herein by reference.

### BACKGROUND

### 1. Field

The disclosure relates to a method of processing a substrate, and a substrate process system, and a method of manufacturing a semiconductor device.

### 2. Description of the Related Art

With the scaling down of semiconductor devices, a reduction in a line width of layers formed on a substrate during the manufacturing process of a semiconductor device and/or an increase in the number of stacking layers are desired, which raises the difficulty of the process, and increases the need for 3D patterning technology that is not currently possible with conventional top-down lithography technology. The development of a patterning or substrate-processing technology that meets such technical needs is desirable.

### SUMMARY

An embodiment is directed to a method of processing a substrate.

An embodiment is directed to a substrate processing system.

An embodiment is directed to a method of manufacturing a semiconductor device including the substrate processing method.

In an embodiment, a substrate processing method includes evaporating, under a pressure below atmospheric pressure, an organic inhibitor compound from a porous medium impregnated with the organic inhibitor compound to provide an evaporated organic inhibitor compound; and selectively depositing the evaporated organic inhibitor compound onto a first region of a substrate at a first pressure in a first chamber including the substrate, to form a self-assembled monolayer including the organic inhibitor compound on the first region of the substrate.

The evaporating of the organic inhibitor compound may be conducted for a predetermined time.

The substrate may include a plurality of regions, and the plurality of regions may include the first region including a first material and a second region including a second material different from the first material.

The organic inhibitor compound may have a vapor pressure of less than or equal to about 0.1 Torr, or less than or equal to about 0.05 Torr at 25° C.

The organic inhibitor compound may include greater than or equal to about 13, greater than or equal to about 14, greater than or equal to about 15, greater than or equal to about 18, or greater than or equal to about 20 carbon atoms.

The organic inhibitor compound may include less than or equal to about 100, less than or equal to about 80, or less than or equal to about 60 carbon atoms.

The organic inhibitor compound may include 13 to 40 carbon atoms.

The organic inhibitor compound may include a reactive group configured to interact with the first material of the substrate. The reactive group may include a phosphonate group, an alkylsilane group, an alkoxysilane group, a chlorosilane group, a thiol group, or a combination thereof.

The organic inhibitor compound may be a chlorosilane compound having an alkyl group of C14 to C30.

The organic inhibitor compound may include a backbone group (for example, an unsubstituted hydrocarbon group) connected to the reactive group. The backbone group may be a hydrocarbon group including greater than or equal to about 12, greater than or equal to about 15, or greater than or equal to about 18, and less than or equal to about 30 carbon atoms.

The method may include providing the organic inhibitor compound in a container including the porous medium, such that the organic inhibitor compound enters a pore (e.g., pores) of the porous medium.

The porous medium may have a porosity of greater than or equal to about 1%, or greater than or equal to about 5%, and less than or equal to about 60%, or less than or equal to about 50%.

The porous medium may be a microporous material, a mesoporous material, or a macroporous material.

The porous medium may include a linear material or a three-dimensional network comprising the linear material. The linear material may have a thickness of greater than or equal to about 0.1 micrometers (μm), greater than or equal to about 0.5 μm, greater than or equal to about 1 μm, or greater than or equal to about 3 μm. The thickness may be less than or equal to about 1000 μm, less than or equal to about 500 μm, less than or equal to about 100 μm, or less than or equal to about 90 μm.

The linear material may include a fibrous material, such as a quartz fiber material such as quartz wool, a glass fiber material such as glass wool, a metal fiber material such as metal wool, a heat-resistant synthetic fiber material, or a combination thereof. The metal fiber material may include iron, copper, stainless steel, or a combination thereof.

The porous medium may include glass fiber, quartz fiber, iron fiber, copper fiber, stainless steel fiber, or a combination thereof.

The porous medium may include a compression-molded product of the linear material, a metal foam, a metal felt, or a combination thereof.

The evaporating of the organic inhibitor compound may be performed by a thermal evaporator, for example a vacuum thermal evaporator. The porous medium or a container including the porous medium may be heated to a predetermined temperature. The predetermined temperature may be greater than or equal to about 150° C. or greater than or equal to about 200° C. The predetermined temperature may be less than or equal to about 500° C., or less than or equal to about 300° C.

The first chamber may include a chamber body, and the thermal evaporator may be disposed in a space defined by the chamber body. The thermal evaporator may be coupled to the chamber body (for example, such that the evaporated organic inhibitor compound can flow into the first chamber).

The evaporating of the organic inhibitor compound may be performed at a first pressure. The first pressure may be less than or equal to about 10⁻³ Torr, less than or equal to about 10⁻⁴ Torr, or less than or equal to about 10⁻⁵ Torr.

In an embodiment, the first material may include a dielectric material, and the second material may include a metal, an organic material, or a nitride. The nitride may include a silicon nitride. In an embodiment, the first material may include a metal, an organic material, or a nitride, e.g., silicon nitride, and the second material may include a dielectric material.

The dielectric may include a silicon oxide (for example, SiOₓ, wherein x is greater than 0 and less than or equal to about 2), an aluminum oxide (for example, Al₂Oₓ, wherein x is greater than 0 and less than or equal to about 3), a hafnium oxide (for example, HfOₓ, wherein x is greater than 0 and less than or equal to about 2), a zirconium oxide (for example, ZrOₓ, wherein x is greater than 0 and less than or equal to about 2), or a combination thereof. The metal may include copper (Cu), ruthenium (Ru), molybdenum (Mo), or a combination thereof. The organic material may include amorphous carbon, a photoresist, or a combination thereof.

The method may include monitoring a thickness of the self-assembled monolayer and stopping deposition when the thickness of the self-assembled monolayer reaches greater than or equal to about 50% of a maximum value or reaches 80% to 100% of the maximum value.

The predetermined time (deposition time) may be greater than or equal to about 30 seconds and less than about 300 seconds, or less than or equal to about 290 seconds.

The substrate (or the first region) on which the self-assembled monolayer is formed may have a water contact angle of greater than or equal to about 102° and less than or equal to about 120°.

The self-assembled monolayer may have a tilting angle, confirmed by near edge X-ray absorption fine structure (NEXAFS) analysis, of less than or equal to about 50°, or less than or equal to about 45°. The tilting angle may be greater than or equal to about 20°, greater than or equal to about 25°, greater than or equal to about 30°, or in a range of about 32° to about 41°.

The method may further include performing, in a second chamber, atomic layer deposition on the substrate including the self-assembled monolayer of the organic inhibitor compound (for example, on the first region) to selectively deposit a thin film (or coating) on a second region of the substrate (for example, a region not including the self-assembled monolayer).

By the deposition, a substrate including the thin film (or coating), or a pattern thereof, may be obtained.

The atomic layer deposition may include: supplying a thin-film precursor gas into the second chamber; supplying an inert gas into the second chamber to purge excess thin-film precursor gas; supplying a co-reactant for reaction with the thin-film precursor gas into the second chamber; and supplying an inert gas into the second chamber to purge excess co-reactant.

The method may further include removing the self-assembled monolayer from the substrate.

The removing of the self-assembled monolayer may be performed in the presence or absence of a liquid, e.g., in a dry manner, a wet manner, or a combination thereof. The dry manner may include purging an inert gas. The wet manner may involve use of an organic solvent. The wet manner may include sonification, swabbing, or a combination thereof.

In an embodiment, the thin film (for example, the coating) has a predetermined thickness, and in a substrate including the thin film, a selectivity obtained by the following equation may be greater than or equal to about 0.8:

$$selectivty ( s ) = \frac{{θ}_{GA} - {θ}_{NGA}}{{θ}_{GA} + {θ}_{NGA}}$$

wherein
Θ_{NGA}: A coating amount (for example, an amount in mole or atomic %) deposited on a first region (non-growth area: NGA); and
Θ_{GA}: a coating amount (for example, an amount in mole or atomic %) deposited on a second region (growth area: GA).

The predetermined thickness may be in a range of about 3 nanometers (nm) to about 10 nm, about 4 nm to about 8 nm, about 2.5 nm to about 5 nm, or about 3 nm.

The selectivity (s) may be greater than or equal to about 0.87.

The thin-film precursor gas may include hafnium, strontium, titanium, barium, ruthenium, molybdenum, cobalt, copper, or a combination thereof.

An embodiment is directed to a substrate processing system, and the substrate processing system includes a first chamber configured to perform self-assembled monolayer (SAM) treatment.

The first chamber includes a body, a substrate holder, and a heated evaporator (for example, a vacuum heated evaporator).

The heated evaporator includes a porous medium configured to be impregnated with an organic inhibitor compound and a heating element, and the heated evaporator is disposed inside the body or is disposed outside the body and is connected to the body.

The first chamber (or the substrate holder) may further include a heater configured to heat a substrate to a desired temperature.

The substrate processing system may further include a pressure-controlling element configured to control pressure of an internal space of the body and, optionally, an internal space of the heated evaporator.

The pressure-controlling element may be connected to the body or the heated evaporator (for example, to an exhaust port).

The heated evaporator may further include a container accommodating the porous medium.

Details regarding the porous medium are as described herein.

The heating element may be configured to heat the porous medium or the container including the porous medium to a predetermined temperature.

The predetermined temperature may be greater than or equal to about 150° C. or greater than or equal to about 200° C.

The predetermined temperature may be less than or equal to about 500° C. or less than or equal to about 300° C.

The substrate processing system may further include a second chamber configured to perform an atomic layer deposition process.

The substrate processing system may further include an element configured to transfer a substrate on which a self-assembled monolayer is formed in the first chamber to the second chamber.

An embodiment is directed to a method of manufacturing a semiconductor device. The method of manufacturing a semiconductor device includes forming a dielectric layer on a substrate; and selectively depositing one or more atomic layers on the dielectric layer, where depositing the one or more atomic layers includes: evaporating, under a pressure below atmospheric pressure, an organic inhibitor compound from an organic inhibitor compound-impregnated porous medium to provide a evaporated organic inhibitor compound; and selectively depositing the evaporated organic inhibitor compound onto a first region of the substrate under a first pressure in a first chamber including the substrate, for a predetermined time, to form a self-assembled monolayer including the organic inhibitor compound on the first region of the substrate.

According to an embodiment, a self-assembled monolayer of an organic inhibitor compound may be formed on a desired region of a substrate within a shortened time.

The organic inhibitor compound in the self-assembled monolayer formed according to an embodiment may exhibit improved vertical orientation and water contact angle, and may exhibit improved selectivity in a subsequent atomic layer deposition process.

### BRIEF DESCRIPTION OF THE DRAWINGS

The above and other aspects, features, and advantages of certain exemplary embodiments will be more apparent from the following detailed description taken in conjunction with the accompanying drawings.

FIG. 1A is a schematic cross-sectional view of a portion (a first chamber) of a substrate processing system according to an embodiment.

FIG. 1B is a schematic view of a portion (a container in which a porous medium is contained) of a substrate processing system according to an embodiment. FIG. 1B illustrates enlarged images of various porous media, but the porous medium of an embodiment is not limited thereto.

FIG. 2 is a schematic cross-sectional view of a portion (the first chamber) of a substrate processing system according to an embodiment.

FIGS. 3A and 3B are schematic views illustrating a tilting angle of molecules, and FIG. 3C illustrates both an incidence angle of X-rays in NEXAFS analysis and a tilting angle of inhibitor molecules.

FIG. 4 is a schematic cross-sectional view illustrating a portion (a second chamber for atomic layer deposition) of a substrate processing system according to an embodiment.

FIGS. 5A, 5B, 5C, and 5D are schematic views illustrating deposition of a self-assembled monolayer and subsequent atomic layer deposition on a substrate including a plurality of regions (for example, on a patterned substrate) in an embodiment.

FIGS. 6A, 6B, 6C, and 6D are schematic views illustrating deposition of a self-assembled monolayer and subsequent atomic layer deposition on a substrate including a plurality of regions (for example, on a patterned substrate) in an embodiment.

FIGS. 7A, 7B, and 7C are schematic views illustrating deposition of a self-assembled monolayer and subsequent atomic layer deposition on a substrate including a plurality of regions (for example, on a patterned substrate) in an embodiment.

FIGS. 8A and 8B schematically illustrate a beam arrangement of an apparatus for NEXAFS analysis.

FIG. 9 illustrates a cross-sectional view of a bubble-type canister used in Reference Example 1.

FIGS. 10A, 10B, and 10C illustrate NEXAFS analysis results of self-assembled monolayers deposited in Preparation Example 1 and Reference Examples 1 and 2.

FIG. 11 is a graph illustrating a change in deposition thickness of an organic molecular compound with respect to deposition time in Experimental Example 1.

FIG. 12 schematically illustrates a first region (a non-growth region) and a second region (a hafnium oxide growth region) in Preparation Example 2.

FIG. 13 schematically illustrates a first region (a non-growth region) and a second region (a ruthenium growth region) in Preparation Example 3.

### DETAILED DESCRIPTION

Advantages and features of the techniques described hereinafter, and methods of achieving them, will become apparent with reference to the exemplary embodiments described below in further detail in conjunction with the accompanying drawings. However, the embodiments should not be construed as being limited to the exemplary embodiments set forth herein. If not defined otherwise, all terms (including technical and scientific terms) as used herein may be defined as commonly understood by one having ordinary skill in the art. The terms defined in a generally-used dictionary may not be interpreted ideally or exaggeratedly unless clearly defined.

In addition, unless explicitly described to the contrary, the word “comprise” and variations such as “comprises” or “comprising,” will be understood to imply the inclusion of stated elements but not the exclusion of any other elements.

In the drawings, the thickness of layers, films, panels, regions, etc., are exaggerated for clarity. Like reference numerals designate like elements throughout the specification.

It will be understood that when an element such as a layer, film, region, or substrate is referred to as being “on” another element, it can be directly on the other element or intervening elements may also be present. In contrast, when an element is referred to as being “directly on” another element, there are no intervening elements present.

As used herein, the singular forms “a,” “an,” and “the” are intended to include the plural forms, including “at least one,” unless the context clearly indicates otherwise. For example, the wording “semiconductor nanoparticle” may refer to a single semiconductor nanoparticle or may refer to a plurality of semiconductor nanoparticles. “At least one” is not to be construed as being limited to “a” or “an.” “Or” means “and/or.” As used herein, the term “and/or” includes any and all combinations of one or more of the associated listed items.

It will be understood that, although the terms “first,” “second,” “third” etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, “a first element,” “component,” “region,” “layer”, or “section” discussed below could be termed a second element, component, region, layer, or section without departing from the teachings of the present embodiments.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±10%, 5%, or 3% of the stated value.

In the drawings, portions not related to the description have been omitted for clarity of explanation of an embodiment, and the same reference numerals are used throughout the specification for the same or similar elements.

Hereinafter, “upper” or “on” may include not only being directly above, below, left, or right in contact, but also being above, below, left, or right without contact.

In addition, when a portion is described as “including” a certain component, it means that, unless specifically stated otherwise, it does not exclude other components but may further include other components.

As used herein, “a combination thereof” refers to a mixture, laminate, composite, alloy, blend, or the like of the constituents.

As used herein, a porous medium refers to a material including a pore or a plurality of pores. In an embodiment, the pore may be filled with a gas or a liquid. The porous medium may further include a supporting structure, e.g., a skeletal material (for example, a frame or a matrix) of the porous medium may be a solid.

As used herein, a reduced-pressure state refers to a pressure lower than atmospheric pressure, less than or equal to about 1 atmosphere (atm), or less than or equal to about 100 pascals (Pa), less than or equal to about 1 Pa, or less than or equal to about 0.1 Pa, or less than or equal to about 1 Torr or less than or equal to about 0.1 Torr.

With increasing circuit density and scaling down of semiconductor devices (for example, semiconductor memory chips such as DRAM/NAND), dimensions of connection portions included in these devices (for example, via holes or trenches), various structures, and dielectric materials disposed between them (for example, line widths) decrease to several tens of nanometers, and the number of layers to be stacked within the device is increasing. Accordingly, manufacturing a semiconductor chip for next-generation devices may include three-dimensional (3D) patterning of characteristics, rather than conventional top-down lithography technology.

Area selective deposition (ASD) has potential to significantly improve current manufacturing approaches by introducing a bottom-up process that selectively deposits robust and uniform thin films onto a patterned substrate. ASD may utilize a self-assembled monolayer (SAM) of a predetermined material (for example, an organic molecular compound, hereinafter referred to as an inhibitor) such as an organic compound (for example, that has a chemical selectivity related to deposition) to propagate, to a next step, a pattern possessed by a substrate prior to processing, thereby providing a pattern of a desired coating material on the substrate to be processed.

For example, in a subsequent substrate processing step (for example, atomic layer deposition), deposition of a coating material (for example, a metal or an oxide thereof) may be inhibited and prevented on a formed self-assembled monolayer, such that the formed self-assembled monolayer may be utilized as a masking material.

In a self-assembled monolayer (SAM), an organic inhibitor compound may exhibit a relatively low vapor pressure. A self-assembled monolayer (SAM) may be a molecular layer attached to a surface, for example by a chemical bond, and adopting a preferred orientation with respect to the surface of a substrate and, optionally, to each other. The SAM may generally include an organized layer of amphiphilic molecules in which one end of the molecule, that is, a “head group,” exhibits a specific and reversible affinity for a substrate. Selection of the head group depends on the application of the SAM, and the type of SAM compound may be determined according to the substrate used. Generally, the head group is connected to an alkyl chain whose tail or “terminal end” can be functionalized, for example to vary wetting and interfacial properties. Molecules forming the SAM selectively attach to one material rather than another material (for example, metal versus dielectric), enabling selective subsequent deposition (for example, ALD) on a material not coated with the SAM (or alternatively on a material coated with the SAM).

The organic inhibitor compound may have a predetermined chemical structure as described herein, and may accordingly be vapor deposited (for example, thermally evaporated) onto a substrate (for example, a pre-patterned substrate, such as a pre-treated wafer) having a plurality of regions including different materials (for example, a first region including a first material and a second region including a second material). The organic inhibitor compound may form a SAM on the first region but may not substantially form a SAM on the second region. The first region and the second region may correspond to a non-growth area in a subsequent deposition process of a coating material.

The SAM may be formed by a wet process or a vapor-phase process. In the wet process, the pre-patterned substrate may be exposed (for example, by dipping or spin coating) to the organic inhibitor compound in a liquid state to form the SAM. However, the present inventors have found that such a wet process may require a very long time (for example, greater than or equal to about 24 hours, or about 48 hours) to form a SAM having a desired quality, and, more importantly, a SAM formed by the wet process may not provide a desired level of selectivity in a subsequent deposition process of a coating material. The wet process may also have a drawback such as a low compatibility with subsequent semiconductor processes.

In a vapor-phase process, an evaporated organic inhibitor compound may be deposited onto a substrate using a carrier gas and may, for example, involve the use of a carrier gas and a bubbler-type canister. However, the present inventors have found that such a vapor-phase process may not form a SAM of desired quality depending on the chemical structure of the organic inhibitor compound.

The organic inhibitor compound may have a head group and a tail group, and the head group and the tail group may be connected by a backbone (for example, an alkane chain). Although an increase in the number of carbon atoms in the backbone may provide improved blocking performance in a subsequent substrate processing step (for example, atomic layer deposition), such an increase in the number of carbon atoms in the backbone may cause a drastic decrease in the vapor pressure of the organic inhibitor compound, making it difficult for the manufactured SAM to exhibit a desired level of quality. In other words, the present inventors have found that, when the number of carbon atoms in the backbone is relatively large (for example, greater than or equal to about 15), a desired ALD blocking performance may be obtained, but such an organic inhibitor compound tends to have extremely low vapor pressures at room temperature, making it very difficult to form a SAM by vapor-phase deposition. On the other hand, when the number of carbon atoms in the backbone of a SAM inhibitor is relatively small (for example, less than or equal to about 12), the SAM may be provided by vapor-phase deposition within a desired time. However, the present inventors have also found that the SAM manufactured in this manner may exhibit unsatisfactory results in terms of an ALD blocking performance.

An embodiment as described herein may solve such problems, and in an advantageous feature, the embodiments may include conventional techniques. A substrate processing system of the embodiment and a processing method using the same include ASD technology and may contribute to reducing manufacturing time and cost of a semiconductor device through a relatively simple process. A substrate processing system of an embodiment and a substrate processing method using the same may contribute to providing a self-aligned interconnect or a feature and may address a misalignment issue at a pattern line width of several nanometers. A substrate processing system of an embodiment and a substrate processing method using the same may provide patterned 3D structures and may be utilized in integration processes of various semiconductor devices.

An embodiment provides a substrate processing system and a substrate processing method capable of implementing area selective atomic layer deposition. An embodiment is directed to forming a self-assembled monolayer of an organic inhibitor compound or a pattern thereof on a predetermined substrate.

In an embodiment, a substrate processing system may include a first chamber and, optionally, a second chamber. The first chamber is a SAM processing chamber used to perform a self-assembled monolayer treatment process. The second chamber is an ALD processing chamber used to perform an atomic layer deposition process.

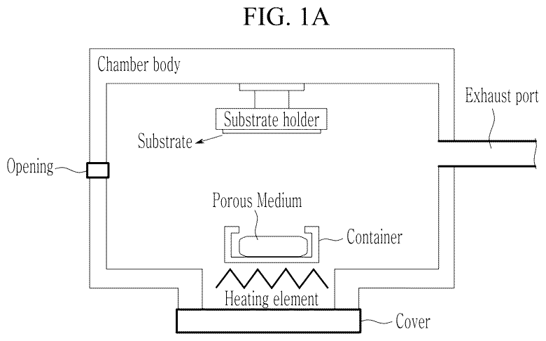

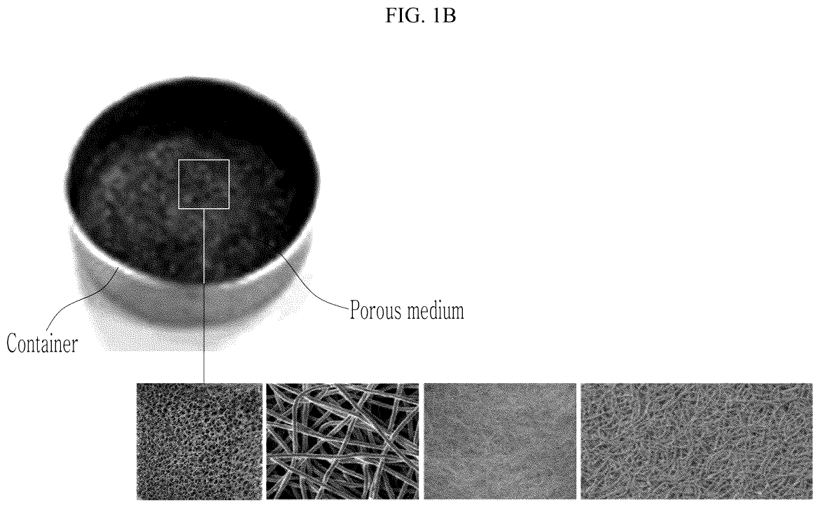

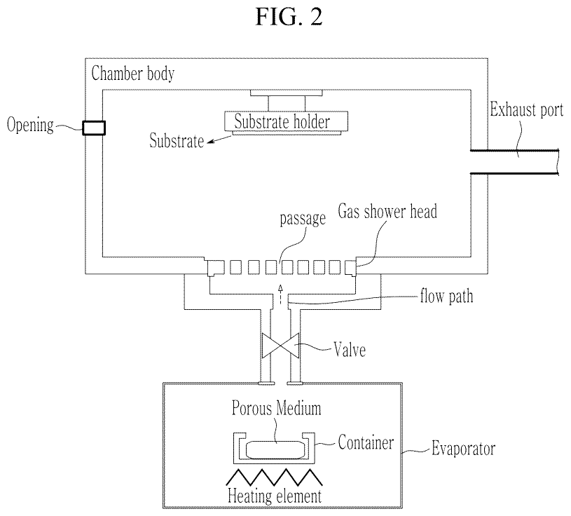

Hereinafter, the first chamber will be described in more detail with reference to the drawings. FIGS. 1A and 2 illustrate schematic cross-sectional views of the first chamber according to an embodiment. Referring to FIGS. 1A and 1B, the first chamber includes a chamber body (hereinafter also referred to as “body”), a substrate holder, and a heated evaporator. In FIG. 1, a porous medium, a container, and a heating element may correspond to the heated evaporator. The first chamber may further include a cover, and the body together with the cover may define an interior of the chamber.

In the interior of the chamber, a substrate holder may be disposed. A heater (not shown) may further be disposed in the substrate holder or in the interior of the chamber to control a temperature of the interior of the chamber or the substrate during formation of a self-assembled monolayer. The heater is not particularly limited and may be appropriately selected. In an embodiment, the heater may be a resistive heater. The heater may be configured to heat the substrate holder to a predetermined temperature. The predetermined temperature may be in a range from about 100° C., about 150° C., about 200° C., about 250° C., about 300° C. to about 350° C., about 400° C., about 450° C., about 500° C., about 550° C., or about 600° C. In an embodiment, the predetermined temperature may be in a range from about 100° C. to about 500° C. or from about 150° C. to about 300° C.

The heated evaporator may be configured to convert an organic inhibitor compound precursor into a vapor and to supply the vaporized organic inhibitor compound into the interior of the chamber (for example, to a processing region). The heated evaporator may be a vacuum-type heated evaporator.

In an embodiment, the heated evaporator may be present in the interior of the chamber, as illustrated in FIG. 1A. In this case, a pressure of the heated evaporator may also be controlled by pressure control of the first chamber.

In an embodiment, the heated evaporator may be disposed outside the chamber body and connected to the body, as illustrated in FIG. 2. A fluid communicating member (for example, a gas showerhead or any pipe (for example, a flow path), or a combination thereof) may be connected between them. The gas showerhead may be directly or indirectly connected to the chamber body. The gas showerhead may include a plurality of passages (or a porous plate providing the passages). The gas showerhead may or may not further include a flow path (for example, a gas inlet line). The passages of the gas showerhead may deliver vapor from the heated evaporator to the processing region, for example, in a straight direction, enabling fluid communication.

The fluid communicating member (for example, a pipe) may or may not further include a valve for controlling gas flow from the evaporator to the chamber. When the fluid communicating member includes a valve, pressure of the interior of the first chamber and pressure of the interior of the evaporator may be simultaneously controlled by opening the valve, but this is not limiting. When the fluid communicating member includes a valve, pressure of the interior of the evaporator may be independently controlled by a pressure-controlling device (not shown) separately provided in the evaporator while keeping the valve closed.

In an embodiment, an inhibitor compound may include a small-molecule inhibitor, for example an organic compound such as an amino-silane compound or a perfluorobenzyl-silane compound. Examples of such small-molecule inhibitor compounds include (N,N-dimethylamino)trimethyl silane, (N,N-dimethylamino) triisopropyl silane, (N,N-dimethylamino)pentamethyl disilane, (N,N-diethylamino) trimethyl silane, bis(N,N-dimethylamino)dimethylsilane, perfluorobenzyl monochlorosilane, perfluorobenzylpropyl monochlorosilane, and the like, but are not limited thereto. Using or applying a small-molecule inhibitor compound may include independently controlling pressure of the interior of the evaporator (that is, differently from pressure of the interior of the chamber) by the valve.

The heated evaporator includes a porous medium configured to be impregnated with the organic inhibitor compound and a heating element. The heated evaporator may further include a container (for example, a crucible or a stainless steel container) accommodating the porous medium. The organic inhibitor compound (or the container accommodating the porous medium) may be heated to a temperature sufficient for vaporization by the heating element.

In an embodiment, the porous medium may have a porosity of greater than or equal to about 1%, or greater than or equal to about 5%, greater than or equal to about 10%, greater than or equal to about 15%, greater than or equal to about 20%, greater than or equal to about 25%, greater than or equal to about 30%, or greater than or equal to about 35%. In an embodiment, the porous medium may have a porosity of less than or equal to about 60%, less than or equal to about 55%, less than or equal to about 50%, less than or equal to about 48%, less than or equal to about 45%, or less than or equal to about 40%. The porosity may be obtained by a BET (Brunauer, Emmett and Teller) measurement method but is not limited thereto.

A BET measurement is based on principles of gas adsorption and may provide information on specific surface area (square meters per gram (m²/g)), pore size, pore volume, and pore size distribution. In the BET measurement, a gas (typically nitrogen) is adsorbed onto a sample to measure a specific surface area of the sample surface, and sizes and distributions of pores. For example, the BET measurement may analyze open pores but is not limited thereto. Specific measurement methods are known, provide easy and reproducible results, and the equipment is commercially available.

The porous medium may be a microporous material, a mesoporous material, or a macroporous material.

In an embodiment, the porous medium may have a pore size or an average pore size of greater than or equal to about 0.5 nm, greater than or equal to about 1 nm, greater than or equal to about 2 nm, greater than or equal to about 5 nm, greater than or equal to about 10 nm, greater than or equal to about 15 nm, greater than or equal to about 20 nm, greater than or equal to about 25 nm, greater than or equal to about 30 nm, greater than or equal to about 35 nm, greater than or equal to about 40 nm, greater than or equal to about 45 nm, greater than or equal to about 50 nm, greater than or equal to about 55 nm, greater than or equal to about 60 nm, greater than or equal to about 65 nm, greater than or equal to about 70 nm, greater than or equal to about 75 nm, greater than or equal to about 80 nm, greater than or equal to about 85 nm, greater than or equal to about 90 nm, greater than or equal to about 95 nm, greater than or equal to about 100 nm, greater than or equal to about 200 nm, greater than or equal to about 300 nm, greater than or equal to about 400 nm, greater than or equal to about 500 nm, greater than or equal to about 600 nm, greater than or equal to about 700 nm, greater than or equal to about 800 nm, or greater than or equal to about 900 nm.

The pore size or the average pore size may be less than or equal to about 1 millimeters (mm), less than or equal to about 0.7 mm, less than or equal to about 0.5 mm, less than or equal to about 0.3 mm, less than or equal to about 0.1 mm, less than or equal to about 0.08 mm, less than or equal to about 0.05 mm, less than or equal to about 0.01 mm, less than or equal to about 10 micrometers (μm), less than or equal to about 9 μm, less than or equal to about 8 μm, less than or equal to about 7 μm, less than or equal to about 6 μm, less than or equal to about 5 μm, less than or equal to about 4 μm, less than or equal to about 3 μm, less than or equal to about 2 μm, less than or equal to about 1 μm, less than or equal to about 950 nm, less than or equal to about 700 nm, less than or equal to about 500 nm, or less than or equal to about 300 nm.

The porous medium may include a linear material or a three-dimensional network of the linear material. The linear material may have a length to diameter ration (L/D) of greater than 10, greater than 50, greater than 100, greater than 500, or greater than 1,000, and the linear material may have a diameter of greater than or equal to about 0.1 μm, greater than or equal to about 0.5 μm, greater than or equal to about 1 μm, greater than or equal to about 1.5 μm, greater than or equal to about 2 μm, greater than or equal to about 2.5 μm, greater than or equal to about 3 μm, greater than or equal to about 5 μm, greater than or equal to about 7 μm, greater than or equal to about 9 μm, greater than or equal to about 10 μm, greater than or equal to about 15 μm, greater than or equal to about 20 μm, greater than or equal to about 25 μm, greater than or equal to about 30 μm, greater than or equal to about 35 μm, greater than or equal to about 40 μm, greater than or equal to about 45 μm, greater than or equal to about 50 μm, greater than or equal to about 60 μm, greater than or equal to about 70 μm, greater than or equal to about 80 μm, greater than or equal to about 90 μm, greater than or equal to about 100 μm, greater than or equal to about 150 μm, greater than or equal to about 200 μm, greater than or equal to about 250 μm, greater than or equal to about 300 μm, greater than or equal to about 350 μm, greater than or equal to about 400 μm, greater than or equal to about 450 μm, greater than or equal to about 500 μm, greater than or equal to about 550 μm, or greater than or equal to about 600 μm.

The diameter may be less than or equal to about 1000 μm, less than or equal to about 900 μm, less than or equal to about 800 μm, less than or equal to about 700 μm, less than or equal to about 560 μm, less than or equal to about 490 μm, less than or equal to about 380 μm, less than or equal to about 230 μm, less than or equal to about 190 μm, less than or equal to about 100 μm, or less than or equal to about 90 μm.

The linear material may include a quartz fiber material such as quartz wool, a glass fiber material such as glass wool, a metal fiber material such as metal wool, a heat-resistant synthetic (e.g., polymeric) fiber material, or a combination thereof. The metal fiber material may include iron, copper, stainless steel, or a combination thereof.

The porous medium may include a material obtained by compressing the linear material (that is, a compression-molded product), a metal mesh, a metal foam, a metal felt, or a combination thereof. The metal foam may be an open-cell type or a closed-cell type.

The organic inhibitor compound may have a vapor pressure of less than or equal to about 0.1 Torr, less than or equal to about 0.05 Torr, less than or equal to about 0.01 Torr, less than or equal to about 0.005 Torr, less than or equal to about 0.001 Torr, or less than or equal to about 0.0005 Torr, less than or equal to about 0.0001 Torr, less than or equal to about 5×10⁻⁵ Torr, less than or equal to about 1×10−5 Torr, less than or equal to about 5×10−6 Torr, or less than or equal to about 1×10−6 Torr at 25° C.

The organic inhibitor compound may include greater than or equal to about 10, greater than or equal to about 12, greater than or equal to about 14, greater than or equal to about 15, greater than or equal to about 16, greater than or equal to about 17, greater than or equal to about 18, greater than or equal to about 19, or greater than or equal to about 20 carbon atoms. The number of carbon atoms in the organic inhibitor compound may be less than or equal to about 100, less than or equal to about 90, less than or equal to about 80, less than or equal to about 70, less than or equal to about 60, less than or equal to about 50, less than or equal to about 40, or less than or equal to about 30.

The organic inhibitor compound may include a reactive group configured to interact with the first material of the substrate. The reactive group may include a phosphonate group, an alkylsilane group, an alkoxysilane group, a chlorosilane group, a thiol group, or a combination thereof.

The organic inhibitor compound may include a backbone group (for example, a substituted or unsubstituted hydrocarbon group) connected to the reactive group. The backbone group may be a hydrocarbon group including greater than or equal to about 12, greater than or equal to about 13, greater than or equal to about 14, greater than or equal to about 15, greater than or equal to about 16, greater than or equal to about 17, or greater than or equal to about 18 and less than or equal to about 30, or less than or equal to about 25 carbon atoms.

Unlike a SAM inhibitor having a relatively small number of carbon atoms in the backbone (for example, less than or equal to about 12 carbon atoms), an organic inhibitor compound having a relatively large number of carbon atoms in the backbone (for example, greater than or equal to about 15) has a low vapor pressure at room temperature and is therefore very difficult to use for forming a SAM by vapor-phase deposition. Surprisingly, the present inventors have found that, when an organic inhibitor compound is impregnated into the porous medium described herein and vaporized, even an organic inhibitor compound having greater than or equal to about 15 carbon atoms can form a SAM exhibiting a desired quality, for example, an increased water contact angle.

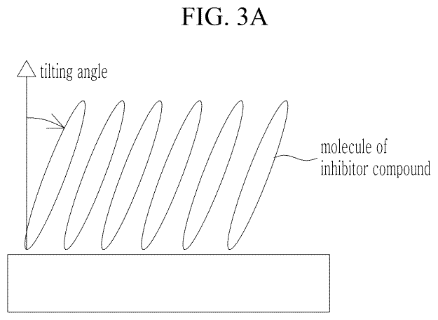

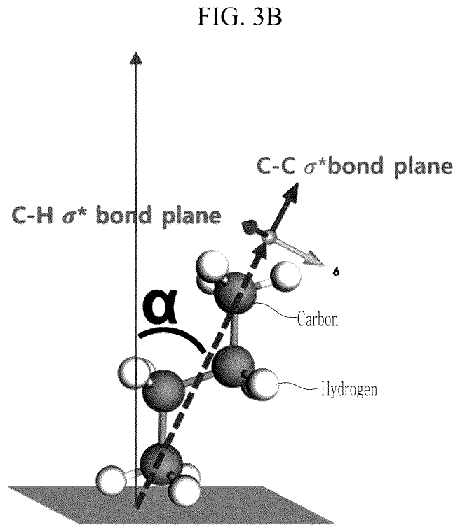

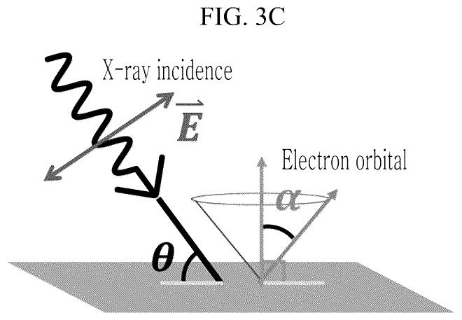

In addition, when the organic inhibitor compound is supplied to the substrate through the thermal evaporator described herein, the molecules of the inhibitor compound in the formed SAM were confirmed to be aligned at a low tilting angle. The tilting angle of the inhibitor compound molecule in the SAM refers to an angle (α) at which the inhibitor molecules tilt with respect to a normal of the substrate, as illustrated in FIG. 3, and may be identified through near edge X-ray absorption fine structure (NEXAFS) analysis of the SAM film. As illustrated in FIG. 3B, intensities shown by CH bonds and C—C bonds differ with respect to an incidence angle (θ) of X-rays, and therefore the tilting or orientation angle can be identified by irradiating X-rays at different incidence angles.

According to findings by the present inventors, a tilting angle of organic inhibitor compound molecules in a SAM formed according to an embodiment including use of a porous medium may be lower than that of a SAM obtained by a wet process, which may indicate improved SAM ordering and excellent surface coverage.

To form a SAM, an organic inhibitor compound to be vaporized may include a head group, a tail group, and a backbone (for example, an alkane chain) connecting the head group and the tail group. The head group may have a reactive group capable of interacting with a substrate and may be appropriately selected in consideration of a material of the substrate on which the SAM is to be formed, and is not particularly limited. The head group may be a functional group configured to be stably adsorbed on a non-growth area of the substrate. In an embodiment, the head group may include a phosphonate group, a thiol group, a silane group, an alkoxy group, a halide group (for example, a chloro group), or a combination thereof.

The tail group may be a group configured to block deposition of a coating precursor in a subsequent process. The tail group may be an inactive or non-reactive group. The tail group may include a hydrocarbon group such as an alkyl group, but is not limited thereto. The backbone may include a hydrocarbon chain (for example, an alkane chain). A number of carbon atoms in the alkane chain may be greater than or equal to about 2, greater than or equal to about 4, greater than or equal to about 7, greater than or equal to about 9, greater than or equal to about 10, greater than or equal to about 11, greater than or equal to about 12, greater than or equal to about 13, greater than or equal to about 14, greater than or equal to about 15, greater than or equal to about 16, greater than or equal to about 17, greater than or equal to about 18, or greater than or equal to about 19. The number of carbon atoms may be less than or equal to about 40, less than or equal to about 35, less than or equal to about 30, less than or equal to about 25, or less than or equal to about 20.

In an embodiment, the organic inhibitor compound may include a compound having a phosphonate group, a compound having a silane functional group, a compound having a thiol group, or a combination thereof. In an embodiment, the organic inhibitor compound having the phosphonate group, the organic inhibitor compound having the thiol group, or the organic inhibitor compound having both the phosphonate group and the thiol group may exhibit affinity for a metal surface (for example, copper) or a region including the metal surface. In an embodiment, an organic inhibitor compound having the silane group may exhibit affinity for a surface of a dielectric (for example, SiO₂) or a region including the dielectric.

Examples of organic inhibitor compounds having the phosphonate group may include phosphonic acid materials such as butylphosphonic acid, pentylphosphonic acid, hexylphosphonic acid, heptylphosphonic acid, and octylphosphonic acid, nonylphosphonic acid, decylphosphonic acid, undecylphosphonic acid, dodecylphosphonic acid, tridecylphosphonic acid, tetradecylphosphonic acid, pentadecylphosphonic acid, hexadecylphosphonic acid, heptadecylphosphonic acid, octadecylphosphonic acid, and nonadecylphosphonic acid, but are not limited thereto.

Examples of organic inhibitor compounds having the thiol group may include butylthiol, pentylthiol, hexylthiol, heptylthiol, octylthiol, nonylthiol, decylthiol, undecylthiol, dodecylthiol (DDT), tridecylthiol, pentadecylthiol, hexadecylthiol, heptadecylthiol, octadecylthiol (ODT), and nonadecylthiol, but are not limited thereto.

A compound having the silane group may include an alkylsilane, an alkoxysilane, a chlorosilane, or a combination thereof. Examples of compounds having the silane group may include a chlorosilane compound such as pentyltrichlorosilane, hexyltrichlorosilane, heptyltrichlorosilane, octyltrichlorosilane, nonyltrichlorosilane, decyltrichlorosilane, undecyltrichlorosilane, dodecyltrichlorosilane, tridecyltrichlorosilane, tetradecyltrichlorosilane, pentadecyltrichlorosilane, hexadecyltrichlorosilane, heptadecyltrichlorosilane, octadecyltrichlorosilane, and nonadecyltrichlorosilane; an alkoxysilane compound such as methyltrimethoxysilane, methyltriethoxysilane, ethyltrimethoxysilane, ethyltriethoxysilane, propyltrimethoxysilane, propyltriethoxysilane, butyltrimethoxysilane, and butyltriethoxysilane, pentyltrimethoxysilane, pentyltriethoxysilane, hexyltrimethoxysilane, hexyltriethoxysilane, heptyltrimethoxysilane, heptyltriethoxysilane, octyltrimethoxysilane, octyltriethoxysilane, nonyltrimethoxysilane, nonyltriethoxysilane, decyltrimethoxysilane, decyltriethoxysilane, undecyltrimethoxysilane, undecyltriethoxysilane, dodecyltrimethoxysilane, dodecyltriethoxysilane, tridecyltrimethoxysilane, tridecyltriethoxysilane, tetradecyltrimethoxysilane, tetradecyltriethoxysilane, pentadecyltrimethoxysilane, pentadecyltriethoxysilane, hexadecyltriethoxysilane, hexadecyltrimethoxysilane, heptadecyltrimethoxysilane, heptadecyltriethoxysilane, octadecyltrimethoxysilane, octadecyltriethoxysilane, nonadecyltrimethoxysilane, nonadecyltriethoxysilane, ethoxysilane, hectadecyltriethoxysilane, heptadecyltriethoxydesyltrimethoxysilane, didesyltrimethoxysilane, didesyltriethoxysilane, (N,N-dimethylamino)trimethylsilane, (N,N-dimethylamino)triisopropylsilane, (N,N-dimethylamino)pentamethyldisilane, (N,N-diethylamino)trimethylsilane, bis(N,N-dimethylamino)dimethylsilane, perfluorobenzyl monochlorosilane, perfluorobenzylpropyl monochlorosilane, tetrakis(dimethylamino) silane, and (N,N-dimethylamino)triethylsilane, but are not limited thereto.

The substrate processing system may further include a pressure-controlling element (not shown) configured to control a pressure of an internal space of the body and, optionally (for example, when the heated evaporator is connected outside the chamber), an internal space of the heated evaporator to a predetermined pressure. The pressure-controlling element may be connected to the body or the heated evaporator. The pressure-controlling element may use known components (for example, various pumps) and is not particularly limited. In an embodiment, vaporization of the organic inhibitor compound may be performed under a reduced pressure (e.g., a pressure below atmospheric pressure). For the predetermined pressure, reference may be made to the first pressure described herein.

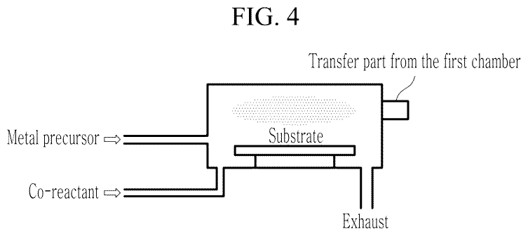

The substrate processing system may further include a second chamber configured to perform an atomic layer deposition process. The second chamber may be any apparatus configured to perform an atomic layer deposition process and is not particularly limited. In an embodiment, referring to FIG. 4, the second chamber includes a chamber body and a substrate support. The chamber body may be provided with a first supply unit for supplying a precursor gas (for example, a metal precursor gas) for forming a coating, a second supply unit for supplying a co-reactant (for example, hydrogen, oxygen, water, or hydrogen peroxide), and an exhaust port. Various types of ALD processing chambers are known or commercially available, and such various ALD processing chambers may also be utilized in the processing system of an embodiment.

The substrate processing system may further include an element (for example, a transfer chamber) configured to transfer a substrate on which a self-assembled monolayer is formed in the first chamber to the second chamber. Such a transfer element is also not particularly limited and an appropriate component (for example, a commercially available one) may be selected.

An embodiment is directed to a method of processing a substrate, and the method includes evaporating, under a reduced pressure, an organic inhibitor compound from a porous medium impregnated with the organic inhibitor compound; and selectively depositing the vaporized organic inhibitor compound onto a first region of the substrate at a first pressure in the first chamber including the substrate, for example for a predetermined time, to form a self-assembled monolayer including the organic inhibitor compound on the first region of the substrate. The deposition may be performed for the predetermined time.

In the method of an embodiment, a substrate including a plurality of regions may be transferred into an interior of the first chamber and mounted on the substrate holder. A transfer method or a mounting method is not particularly limited and may be appropriately selected. In an embodiment, the substrate includes a plurality of regions, and the plurality of regions may include a first region including a first material and a second region including a second material different from the first material. In an embodiment, the first material may include a dielectric, and the second material may include a metal, an organic material, or a nitride. In an embodiment, the first material may include a metal, and the second material may include a dielectric.

The dielectric may include silicon oxide (for example, SiO₂), aluminum oxide (for example, Al₂O₃), hafnium oxide (for example, HfO₂), zirconium oxide (for example, ZrO₂), or a combination thereof. The metal may include copper, ruthenium (Ru), molybdenum (Mo), cobalt (Co), or a combination thereof. The nitride may include silicon nitride. The organic material may include amorphous carbon, a photoresist, or a combination thereof.

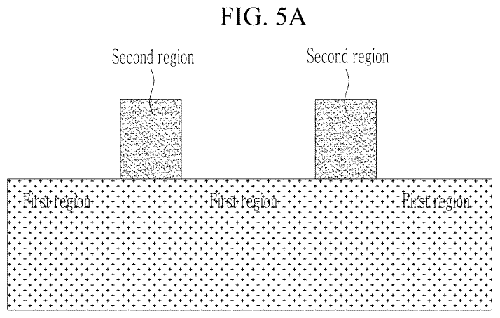

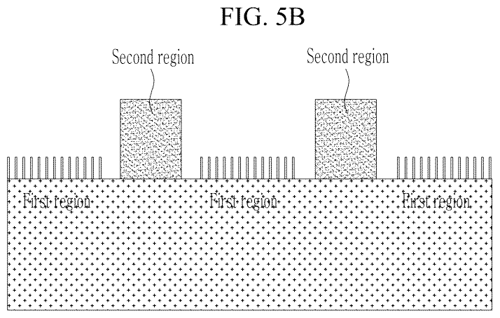

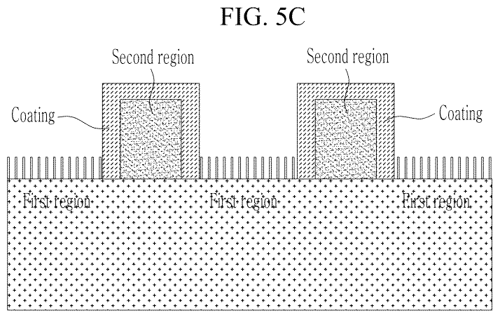

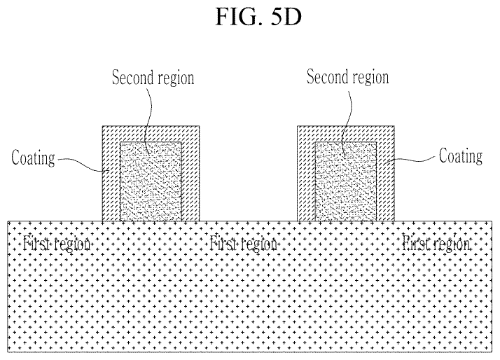

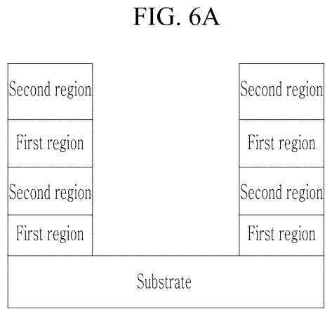

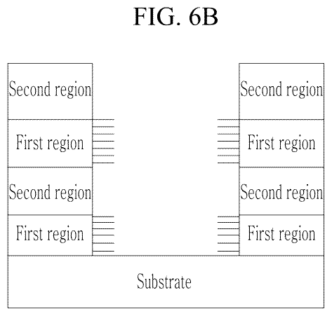

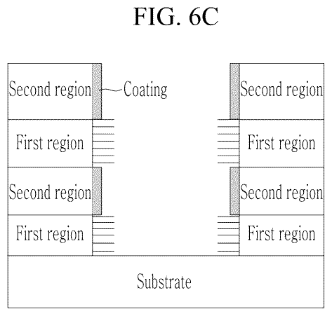

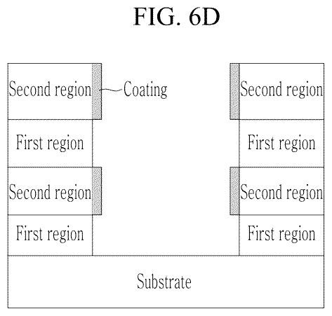

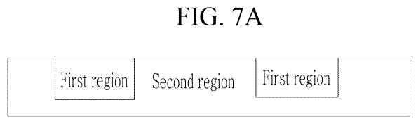

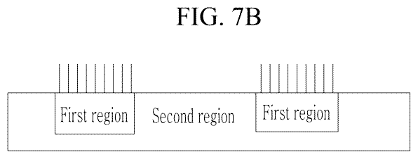

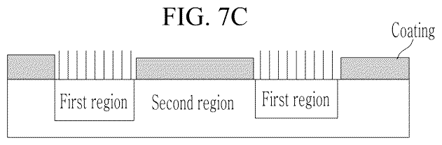

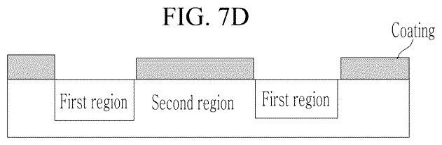

In an embodiment, a substrate including the first region and the second region may be pre-patterned. In an embodiment, the first region of the substrate is a portion on which a self-assembled monolayer is formed, and is a non-growth area (NGA) in which a coating does not grow in a subsequent coating process (for example, atomic layer deposition). In an embodiment, the second region of the substrate is a portion on which the self-assembled monolayer is not formed, and is a growth area (GA) in which a coating grows in the subsequent coating process (for example, atomic layer deposition). An arrangement of the first region and the second region in the substrate is not particularly limited and may take various forms. Referring to FIG. 5A, the pre-patterned substrate may include a wafer made of a first material (SiO₂) and a second region (for example, an amorphous carbon layer, ACL, or a photoresist PR) patterned on the wafer. Referring to FIG. 6A, the pre-patterned substrate may include a Si wafer and an alternating stacked structure of a dielectric layer (for example, SiO₂) and a nitride layer (for example, SiN) disposed on the wafer, in which a side surface of the dielectric layer is the first region and a side surface of the nitride layer is the second region. Referring to FIG. 7A, the pre-patterned substrate may include the first region (for example, SiO₂) and the second region (for example, a region including a metal such as Cu) adjacent to the first region.

In the method of an embodiment, the porous medium is impregnated with the organic inhibitor compound and is, for example, vaporized in the heated evaporator. Details regarding the organic inhibitor compound, the porous medium, and the heated evaporator are as described herein. An impregnation manner is not particularly limited and may be appropriately selected. In an embodiment, the porous medium may be placed in a container, and the organic inhibitor compound or a solution including the organic inhibitor compound may be added to the container. Vaporization of the organic inhibitor compound may be performed at a predetermined temperature and a predetermined pressure. Accordingly, in the method of an embodiment, the porous medium or the container including the porous medium may be heated to the predetermined temperature. The predetermined temperature may be greater than or equal to about 150° C., greater than or equal to about 160° C., greater than or equal to about 170° C., greater than or equal to about 180° C., greater than or equal to about 190° C., or greater than or equal to about 200° C. The predetermined temperature may be less than or equal to about 500° C., less than or equal to about 450° C., less than or equal to about 400° C., less than or equal to about 350° C., or less than or equal to about 300° C. The predetermined pressure may be less than or equal to about 10⁻³ Torr, less than or equal to about 5×10⁻⁴ Torr, less than or equal to about 10⁻⁴ Torr, less than or equal to about 5×10⁻⁵ Torr, less than or equal to about 10⁻⁵ Torr, or less than or equal to about 10⁻⁶ Torr. Such pressure control may be performed by the pressure-controlling means provided in the apparatus of an embodiment.

In the method of an embodiment, vaporization of the organic inhibitor compound may be performed without an additional carrier gas, and may provide significantly improved quality (for example, a high molecular orientation degree and selectivity) compared to vaporization utilizing such a carrier gas.

The vaporized organic inhibitor compound (that is, the organic inhibitor compound gas) may move to a substrate including a plurality of regions and may form a self-assembled monolayer (SAM) including the organic inhibitor compound on the first region. The method of an embodiment may include adjusting a temperature and a pressure inside the chamber to a first temperature and a first pressure, respectively, before forming the SAM on the substrate.

The first pressure may be less than or equal to about 10⁻³ Torr, less than or equal to about 5×10⁻⁴ Torr, less than or equal to about 10⁻⁴ Torr, less than or equal to about 5×10⁻⁵ Torr, less than or equal to about 10⁻⁵ Torr, or less than or equal to about 10⁻⁶ Torr. The first pressure may be greater than or equal to about 10⁻⁸ Torr, greater than or equal to about 10⁻⁷ Torr, or greater than or equal to about 10⁻⁶ Torr. Such pressure control may be performed by pressure-controlling means provided in the apparatus of an embodiment.

The first temperature may be greater than or equal to about 30° C., greater than or equal to about 50° C., greater than or equal to about 70° C., greater than or equal to about 90° C., greater than or equal to about 100° C., greater than or equal to about 120° C., greater than or equal to about 150° C., greater than or equal to about 160° C., greater than or equal to about 170° C., greater than or equal to about 180° C., greater than or equal to about 190° C., or greater than or equal to about 200° C. The first temperature may be less than or equal to about 500° C., less than or equal to about 450° C., less than or equal to about 400° C., less than or equal to about 350° C., or less than or equal to about 300° C.

In an embodiment, when the heated evaporator is connected to the first chamber from outside the first chamber (refer to FIG. 2), the method may include flowing the vaporized organic inhibitor compound into the first chamber. In an embodiment, when the first chamber reaches the first pressure and the first temperature, the vaporized organic inhibitor compound may flow into the first chamber. A temperature of a flow path through which the vaporized organic inhibitor compound moves may be maintained at an elevated temperature. Various components along the flow path may include heaters, or may be conductively heated by a heater in the vicinity, to maintain the temperature. In an embodiment, when the heated evaporator is disposed inside the first chamber (refer to FIG. 1), the vaporized organic inhibitor compound may move from the heated evaporator to the substrate at the first temperature and the first pressure.

According to the method of an embodiment, in the first chamber at the first temperature and the first pressure, the vaporized organic inhibitor compound may be deposited, for example based on its inherent chemical selectivity, onto at least the first region of the substrate to form the SAM on at least the first region of the substrate. For example, referring to FIG. 5B, a self-assembled monolayer (SAM) of the organic inhibitor molecules is formed on the first region of the pre-patterned substrate, and the SAM is not formed on the second region. Referring to FIG. 6B, a self-assembled monolayer (SAM) of the organic inhibitor molecules is formed on the first region of the pre-patterned substrate, and the SAM is not formed on the second region. Referring to FIG. 7B, a self-assembled monolayer (SAM) of the organic inhibitor molecules is formed on the first region of the pre-patterned substrate, and the SAM is not formed on the second region.

In the method of an embodiment, a thickness of the self-assembled monolayer may reach a maximum value according to a deposition time and then may decrease. Accordingly, the method of an embodiment may include monitoring the thickness of the self-assembled monolayer and stopping the deposition when the thickness of the self-assembled monolayer reaches from greater than or equal to about 50%, to less than or equal to about 100% of its maximum value. A time required for the thickness of the self-assembled monolayer to reach its maximum value may vary depending on a type of the porous medium and the organic inhibitor compound, and may be determined by monitoring a change in the thickness according to the deposition time. As confirmed by the present inventors, the method of an embodiment may exhibit a change in molecular arrangement of the organic inhibitor compound depending on the deposition thickness, and such a change in molecular arrangement may affect a selectivity of a coating in a subsequent ASD process.

In an embodiment, the deposition time may be greater than or equal to about 10 seconds, greater than or equal to about 20 seconds, greater than or equal to about 30 seconds, greater than or equal to about 40 seconds, greater than or equal to about 50 seconds, greater than or equal to about 60 seconds, greater than or equal to about 70 seconds, greater than or equal to about 80 seconds, or greater than or equal to about 90 seconds. In an embodiment, the deposition time may be less than or equal to about 10 minutes, less than or equal to about 8 minutes, less than or equal to about 6 minutes, less than or equal to about 5 minutes, less than or equal to about 290 seconds, less than or equal to about 280 seconds, less than or equal to about 270 seconds, less than or equal to about 260 seconds, or less than or equal to about 250 seconds.

In the method of an embodiment, the formed self-assembled monolayer (or the first region of the substrate including the self-assembled monolayer) may have a water contact angle greater than or equal to about 100°, greater than or equal to about 101°, greater than or equal to about 102°, greater than or equal to about 103°, greater than or equal to about 104°, greater than or equal to about 105°, greater than or equal to about 106°, greater than or equal to about 107°, greater than or equal to about 108°, greater than or equal to about 109°, greater than or equal to about 110°, greater than or equal to about 111°, or greater than or equal to about 112°. The water contact angle may be less than or equal to about 130°, less than or equal to about 125°, less than or equal to about 120°, less than or equal to about 119°, less than or equal to about 118°, less than or equal to about 117°, less than or equal to about 116°, or less than or equal to about 115°. A method of measuring the water contact angle is not particularly limited and may be appropriately selected using commercially available equipment.

The self-assembled monolayer may have a molecular tilting angle (α, refer to FIGS. 3A and 3B) confirmed by a near edge X-ray absorption fine structure (NEXAFS) analysis that is less than or equal to about 50°, less than or equal to about 49°, less than or equal to about 48°, less than or equal to about 47°, less than or equal to about 46°, less than or equal to about 45°, less than or equal to about 44°, less than or equal to about 43°, less than or equal to about 42°, less than or equal to about 41°, less than or equal to about 40°, less than or equal to about 39°, less than or equal to about 38°, less than or equal to about 37°, less than or equal to about 36°, less than or equal to about 35°, less than or equal to about 34°, less than or equal to about 33°, less than or equal to about 32°, less than or equal to about 31°, less than or equal to about 30°, or less than or equal to about 29°. The molecular tilting angle may be greater than or equal to about 15°, greater than or equal to about 20°, greater than or equal to about 25°, greater than or equal to about 30°, or in a range of about 32° to about 41°.

The method may further include performing an atomic layer deposition (ALD) in the second chamber on the substrate including the self-assembled monolayer of the organic inhibitor compound. By the ALD, a coating or a thin film may be selectively deposited on the second region of the substrate to obtain the substrate including the thin film of a desired pattern. In an embodiment, the method may include transferring the SAM-treated substrate from the first chamber to the second chamber (also referred to as the ALD chamber) through a transfer chamber after deposition of the SAM material is performed on the substrate in the first chamber. A structure of the transfer chamber and a transfer method are not particularly limited and may be appropriately selected.

The atomic layer deposition process in the second chamber is not particularly limited and may be appropriately selected. In an embodiment, the atomic layer deposition may include supplying a thin-film precursor gas into the second chamber; supplying an inert gas into the second chamber to purge an excess of the thin-film precursor gas; supplying a co-reactant into the second chamber for reaction with the thin-film precursor gas; and supplying the inert gas into the second chamber to purge an excess of the co-reactant, thereby selectively forming a coating on the second region. For example, referring to FIG. 5C, in the pre-patterned substrate, a thin film (hereinafter also referred to as a coating layer) is not formed on the first region on which the self-assembled monolayer (SAM) of the organic inhibitor molecules is formed, whereas the coating layer is formed on the second region on which the SAM is absent. For example, referring to FIG. 6C, in the pre-patterned substrate, the coating layer is not formed on the first region on which the self-assembled monolayer (SAM) of the organic inhibitor molecules is formed, whereas the coating layer is formed on the second region on which the SAM is absent. For example, referring to FIG. 7C, in the pre-patterned substrate, the coating layer is not formed on the first region on which the self-assembled monolayer (SAM) of the organic inhibitor molecules is formed, whereas the coating layer is formed on the second region on which the SAM is absent.

The self-assembled monolayer formed on the first region according to an embodiment may contribute to an improvement of the selectivity in the ALD process. In an embodiment, the substrate including the coating or the thin film may have a predetermined thickness of the coating or the thin film, and may have a selectivity of greater than or equal to about 0.8 as determined by the following Equation:

$$selectivty ( s ) = \frac{{θ}_{GA} - {θ}_{NGA}}{{θ}_{GA} + {θ}_{NGA}}$$

wherein
Θ_{NGA}: a coating amount deposited on a first region (non-growth area: NGA); and
Θ_{GA}: a coating amount deposited on a second region (growth area: GA).

The predetermined thickness may be greater than or equal to about 3 nm and less than or equal to about 5 nm, or may be about 3 nm.

The selectivity may be greater than or equal to about 0.81, greater than or equal to about 0.82, greater than or equal to about 0.83, greater than or equal to about 0.84, greater than or equal to about 0.85, greater than or equal to about 0.86, greater than or equal to about 0.87, greater than or equal to about 0.88, greater than or equal to about 0.89, or greater than or equal to about 0.9. The selectivity may be in a range of about 0.8 to about 1.

The formed coating may be a metal such as copper, hafnium, strontium, titanium, barium, ruthenium, cobalt, or molybdenum, a dielectric such as SiO₂, or a combination thereof. The types of precursor and co-reactant used for forming the coating in the ALD process are not particularly limited and may be appropriately selected depending on the coating to be formed. In an embodiment, the precursor for forming the coating may include copper, hafnium, strontium, titanium, barium, ruthenium, cobalt, molybdenum, or a combination thereof. In an embodiment, the precursor for forming the coating may include an organometallic compound including the metal, for example tetrakis(ethylmethylamino) hafnium, ethyl-benzene ethyl-1,4-cyclohexadiene ruthenium, and the like, but is not limited thereto. The co-reactant may include hydrogen, oxygen, water, hydrogen peroxide, or a combination thereof, but is not limited thereto.

The method may further include removing the self-assembled monolayer from the substrate. For example, referring to FIGS. 5D, 6D, and 7C, the self-assembled monolayer that was present on the first region may be removed from the substrate, and the substrate may be patterned such that a desired coating is formed on the second region. A method of removing the self-assembled monolayer is not particularly limited. The removal of the self-assembled monolayer may be performed by a dry method, a wet method, or a combination thereof. The dry method may include purging an inert gas (for example, nitrogen, argon, helium). The wet method may involve the use of an organic solvent (for example, acetone, methanol, chloroform). The wet method may include sonification, swabbing, or a combination thereof.

According to another embodiment, a method of manufacturing a semiconductor device is provided, the method including forming a dielectric layer on a substrate, and selectively depositing one or more atomic layers on the dielectric layer, wherein the depositing of the one or more atomic layers includes a substrate processing method (for example, a selective deposition method) described herein.

According to still another embodiment, a method of manufacturing a semiconductor device is provided, the method including forming a transistor channel on a substrate, forming a gate dielectric layer on the transistor channel, and forming a gate electrode on the gate dielectric layer, wherein forming the gate electrode includes the selective deposition method of the thin film.

Hereinafter, the exemplary embodiments are illustrated in further detail with reference to examples. However, embodiments of the present disclosure are not limited to the examples.

### EXAMPLES

### Analysis Methods

### [1] NEXAFS Analysis

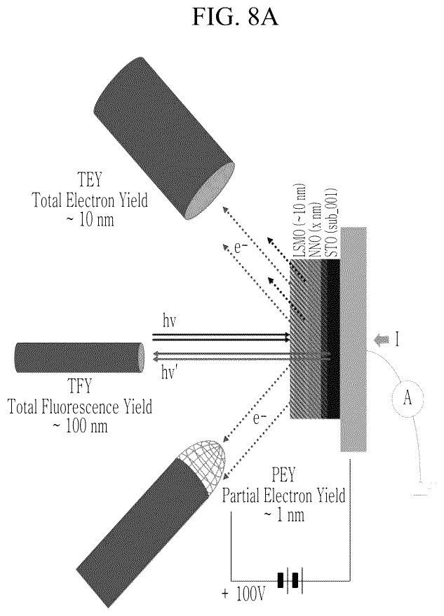

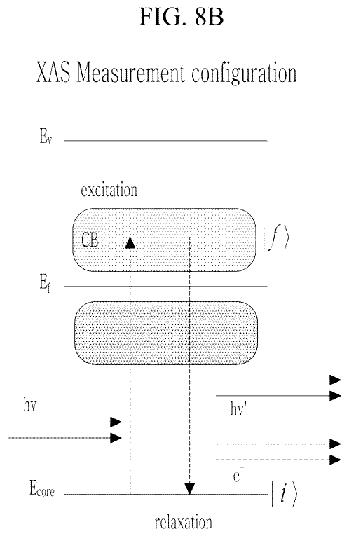

Using NEXAFS equipment including a beamline having the arrangement shown in FIG. 8A and FIG. 8B, a molecular tilting angle of the organic inhibitor compound in the manufactured SAM was measured while changing an incident angle from 20° to 90°. The tilting angle may be determined according to the following relational expression:

Peak intensity for a X-ray incident angle (Θ)

$$I = {\vert 〈 f \vert E \cdot P \vert i 〉 \vert}^{2}$$

$$I = A [ 1 + \frac{1}{2} ( 3 {cos}^{2} θ - 1 ) ( 3 {cos}^{2} α - 1 )$$

In the above equations, θ (theta) is an incident angle of an X-ray beam, α is a molecular tilting angle, I is a peak intensity, E is an electric field vector of the X-ray, P is a momentum of an electron associated with the peak, and A is an arbitrary constant.

### [2] TEM Analysis

A transmission electron microscopy analysis was performed using a PHI Quantes XPS (ULVAC-PHI).

### [3] Measurement of Selectivity

An XPS analysis was performed on the deposited thin film (the thin-film thickness was about 3 nm to about 10 nm) using a Titan G2 TEM system (Thermo Fisher) to measure an amount of coating (for example, a mole amount, atomic % of XPS) in the first region (non-growth area, NGA) and the second region (growth area, GA).

From the measured amount of coating, a selectivity(S) was calculated according to the following Equation:

$$selectivty ( s ) = \frac{{θ}_{GA} - {θ}_{NGA}}{{θ}_{GA} + {θ}_{NGA}}$$

wherein
Θ_{NGA}: a coating amount deposited on a first region (non-growth area: NGA); and
Θ_{GA}: a coating amount deposited on a second region (growth area: GA).

### [4] Measurement of Water Contact Angle

A water contact angle was measured using a DSA 100 contact angle analyzer (KRUSS).

### Example 1

[1] A self-assembled monolayer was formed on the first region in the following manner using a vacuum deposition apparatus (Hanjin Vacuum, HVC-1200DA) including a heated evaporator provided inside the chamber.

A porous medium (a porosity of about 30%, about 1.2 grams) manufactured by compressing stainless steel wool (a fiber diameter, median value: about 50 micrometers) was placed in a container of the heated evaporator, and an organic inhibitor compound, an octadecyltrichlorosilane (hereinafter, ODTS, manufacturer: Gelest, 0.4 g), was poured onto and impregnated into the porous medium.

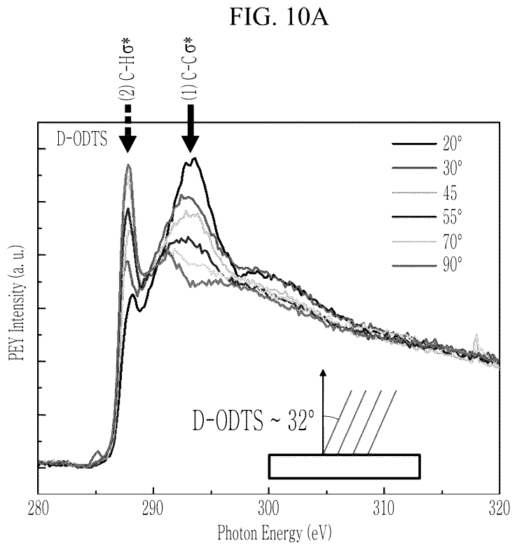

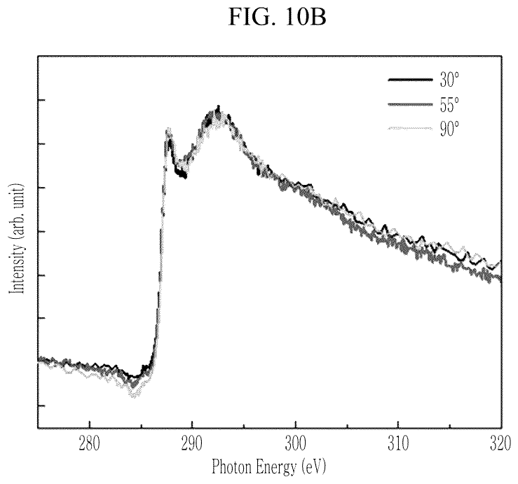

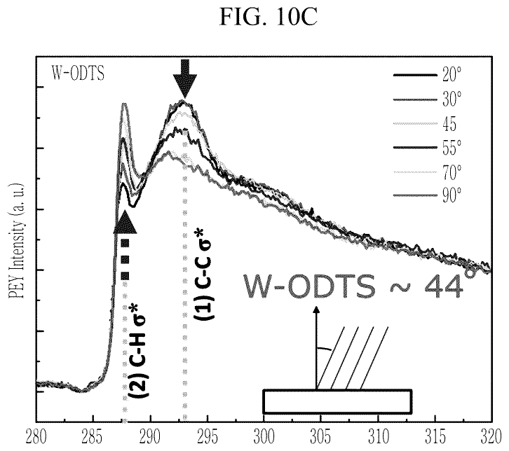

A substrate having the first region including silicon oxide was fixed to a substrate holder as shown in FIG. 1, and a self-assembled monolayer was formed on the first region by heating the heated evaporator to about 150° C. and reducing a pressure in the chamber to about 10⁻⁵ Pa. A deposition time was set to 100 seconds.

[2] A water contact angle and a molecular tilting angle of the organic inhibitor compound were measured for the substrate on which the self-assembled monolayer was formed, and the results were summarized in Table 1 and FIG. 10A.

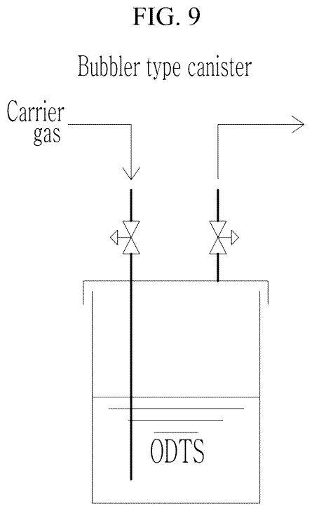

### Comparative Example 1

[1] A SAM was formed on the substrate in the same manner as in Example 1 except that, instead of the heated evaporator including the porous medium, a bubble-type canister as shown in FIG. 9 and nitrogen as a carrier gas were used to generate ODTS gas and supply it to the vacuum deposition apparatus.

[2] A water contact angle and a molecular tilting angle of the organic inhibitor compound were measured for the substrate on which the self-assembled monolayer was formed, and the results were summarized in Table 1 and FIG. 10B.

### Comparative Example 2

[1] An ODTS solution (a concentration: about 4 mM) was prepared by adding ODTS into a beaker containing toluene under a nitrogen atmosphere. A substrate having the first region including silicon oxide was immersed in the ODTS solution for 24 hours to form a SAM on the substrate.

[2] A water contact angle and a molecular tilting angle of the organic inhibitor compound were measured for the substrate on which the self-assembled monolayer was formed, and the results were summarized in Table 1 and FIG. 10C.

TABLE 1

| | Water contact | tilting | Vertical |
|---|---|---|---|
| | angle | angle | orientation |
| Example 1 | 112° | 32° | Yes |
| Comp. Example 1 | 101° | Not measurable | No |
| Comp. Example 2 | 109° | 44° | Yes |

From the results of Table 1 and FIGS. 10A to 10C, it can be confirmed that Embodiment 1, which includes using the organic inhibitor compound impregnated into the porous medium, can form a high-density SAM in a short time. It was confirmed that the manufactured SAM may exhibit improved quality (that is, an increased water contact angle and vertical orientational ordering) compared to the Comparative Examples.

### Comparative Example 3

A SAM deposition process was performed in the same manner as in Embodiment 1 except that the organic inhibitor compound was placed in a container without using the porous medium. It was confirmed that the SAM was not properly formed.

### Experimental Example 1: Characteristics of ODTS SAM Inhibitor According to Deposition Time

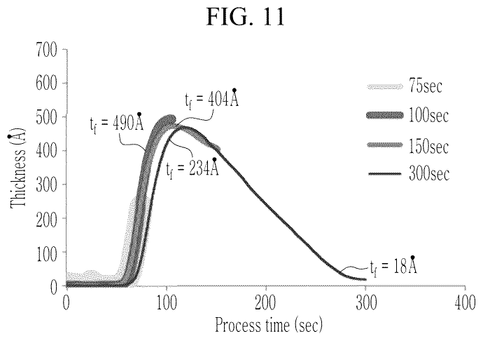

A SAM deposition was performed in the same manner as in Embodiment 1 while varying a deposition time to about 75 seconds, about 100 seconds, about 150 seconds, and about 300 seconds. The results were summarized in Table 2 and FIG. 11.

TABLE 2

| Deposition | | Deposition | | Water contact | Tilting | Vertical |
|---|---|---|---|---|---|---|
| time | | thickness | | angle | angle | orientation |
| 75 | seconds | 234 | Å | 90° | Not measurable | No |
| 100 | seconds | 490 | Å | 112° | 32° | Yes |
| 150 | seconds | 404 | Å | 112° | 41° | Yes |
| 300 | seconds | 18 | Å | 87° | Not measurable | No |

From the results of Table 2 and FIG. 11, it was confirmed that the ODTS SAM inhibitor exhibits a characteristic in which, as the deposition time increases, the thickness increases to a maximum and then gradually decreases, and that a high-density ODTS SAM can be formed when the process is terminated at the maximum thickness (about 100 seconds) or at 80% of the maximum thickness (about 150 seconds).

Evaluation of Formation of Hafnium Oxide by ALD

### Example 2

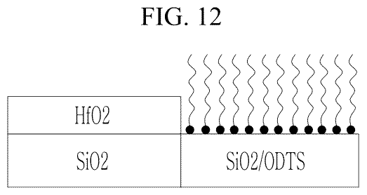

Using a deposition apparatus (LUCIDA C200-PL, NCD), a thermal ALD was carried out as described below to form a hafnium oxide layer, as illustrated in FIG. 12:

(1) A SiO₂ substrate including the SAM prepared in Embodiment 1 was placed in a deposition chamber. Under a chamber pressure of about 0.5 Torr, tetrakis(ethylmethylamino) hafnium was introduced as a metal precursor at a flow rate of 100 standard cubic centimeters per minute (sccm) for 1.5 seconds. Subsequently, argon gas (Ar, 99.999%) was supplied into the atomic layer deposition chamber at a flow rate of 100 sccm for 30 seconds to purge the chamber. Then, under a chamber pressure of about 0.5 Torr, water (H₂O, a co-reactant) was introduced at a flow rate of 100 sccm for 0.5 seconds, and the same purging conditions with argon gas were applied. A deposition temperature was about 150° C., and 26 cycles were performed. A growth per cycle was about 1.15 Å/cycle. It was confirmed that the hafnium oxide layer was not properly formed on the substrate.

(2) As a reference, instead of the SiO₂ substrate including the SAM prepared in Embodiment 1, a bare SiO₂ substrate was placed in the deposition chamber, and a hafnium oxide layer having a thickness of about 2.9 nm was formed in the same manner.

(3) Amounts of hafnium oxide coated on the SiO₂ substrate including the SAM after ALD and on the reference substrate were measured by XPS, and a selectivity was calculated based on the measured coating amounts. The results were summarized in Table 3.

### Comparative Example 4

Except that the SiO₂ substrate including the SAM prepared in Comparative Example 2 was used instead of the substrate of Embodiment 2, an ALD was performed in the same manner to form a hafnium oxide layer. The amount of hafnium oxide coated on the SiO₂ substrate including the SAM after ALD was measured by XPS, and a selectivity was calculated based on the measured coating amount. The results were summarized in Table 3.

TABLE 3

| | Relative selectivity |
|---|---|
| Example 2 | 108% |
| Comp. Example 4 | 100% |

The relative selectivity (%) was calculated as follows:

$$Relative selectivity ( \% ) = [ selectivity of a given substrate / selectivity of a substrate prepared in Reference Example 4 ] \times 100$$

From the results in Table 3, it was confirmed that the deposition of the embodiments can achieve an increased selectivity compared to the comparative examples.

Formation of Metal Ruthenium Film by ALD

### Example 3

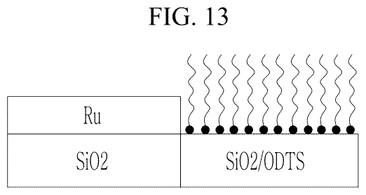

Using a deposition apparatus (LUCIDA C200-PL, NCD), a thermal ALD was carried out as described below to form a ruthenium layer, as illustrated in FIG. 13:

(1) A SiO₂ substrate including the SAM prepared in Embodiment 1 was placed in a deposition chamber. Under a chamber pressure of about 0.2 Torr, ethyl-benzene ethyl-1,4-cyclohexadiene ruthenium was introduced as a metal precursor at a flow rate of about 300 sccm for about 4 seconds. Subsequently, nitrogen gas (N₂, 99.999%) was supplied into the atomic layer deposition chamber at a flow rate of 300 sccm for about 20 seconds to purge the chamber. Then, under a chamber pressure of about 0.5 Torr, oxygen (O₂, a co-reactant) was introduced at a flow rate of 300 sccm for about 5 seconds, and purging was performed with nitrogen gas under the same conditions. A deposition temperature was about 250° C., and a predetermined number of cycles (50, 100, or 150 cycles) was carried out. A growth per cycle was about 1 angstrom per cycle (Å/cycle). It was confirmed that a ruthenium layer was substantially not formed on the substrate.

(2) As a reference, except that a bare SiO₂ substrate was placed in the deposition chamber instead of the SiO₂ substrate including the SAM, ruthenium layers having thicknesses of about 4.55 nm, about 6.99 nm, and about 9.68 nm were formed in the same manner.

(3) After ALD, the amount of ruthenium coated on the SiO₂ substrate including the SAM and on the reference substrates was measured by XPS, and a selectivity was calculated based on the measured coating amounts. The results were summarized in Table 4.

TABLE 4

| | 50 cycle | | 100 cycle | | 150 cycle | |
|---|---|---|---|---|---|---|
| substrate | thickness | selectivity | thickness | selectivity | thickness | selectivity |
| SiO₂/D-ODTS | 0 | 1 | 0 | 1 | 0 | 1 |
| SiO₂ | 4.55 | 0 | 6.99 | 0 | 9.68 | 0 |

From the results in Table 4, it was confirmed that the substrate including the SAM prepared in Embodiment 1 may exhibit an almost perfect blocking performance (that is, a selectivity of 1) with respect to the (ethylbenzyl) (1-ethyl-1,4-cyclohexadienyl) ruthenium (0) (EBECHRu) precursor up to 150 cycles (about 9.68 nm).

Formation of SAM on ACL and Formation of Hafnium Oxide Film by ALD

### Example 4

### [1] Formation of SAM Layer

Except that a pre-patterned substrate including amorphous carbon (an ACL carbon pattern) in the first region (NGA) and SiO₂ in the second region (GA), as illustrated in FIG. 5A, was used as the substrate, a SAM layer was formed in the same manner as in Embodiment 1. The treated substrate included the SAM layer as shown in FIG. 5B.

A water contact angle and a molecular orientational ordering were measured for the substrate including the SAM layer, and the results were summarized in Table 5.

### [2] Formation of Hafnium Oxide Layer by ALD

Except that the patterned substrate including the SAM layer prepared above was used, an ALD process was performed in the same manner as in Embodiment 2 to obtain a patterned substrate having a hafnium oxide layer formed on the second region (ACL), as shown in FIG. 5C. A water contact angle, a molecular orientational ordering, and a selectivity were measured for the fabricated substrate, and the results were summarized in Table 5.

When the self-assembled monolayer is removed from the obtained substrate, a substrate including a selectively deposited HfO₂ hard mask layer only on the ACL (GA) surface, as illustrated in FIG. 5D, may be obtained.

TABLE 5

| | | ODTS SAM characteristics | | ALD HfO₂ blocking performance (26 cycle) | | |
|---|---|---|---|---|---|---|
| | | water | vertical | water | | |
| | | contact | orientation | contact | | |
| | materials | angle | (tilting angle) | angle | thickness | Selectivity |
| NGA | SiO₂ | 112° | ◯ (32°) | 108° | 0 (island) | 0.88 |
| GA | ACL | 70° | X (none) | 52° | 3.1 | |

From the results in Table 5, it was confirmed that the substrate treated according to the embodiment exhibited excellent selectivity for the HfO₂ thin film with respect to the ACL.

The embodiments described herein provide a substrate processing method, the method including evaporating, under a reduced pressure, an organic inhibitor compound from a porous medium impregnated with the organic inhibitor compound; and selectively depositing the evaporated organic inhibitor compound onto a first region of a substrate in a first chamber including the substrate, for example, for a predetermined time and under a first pressure, to form a self-assembled monolayer including the organic inhibitor compound on the first region of the substrate.

In an embodiment, the substrate includes a plurality of regions, and the plurality of regions includes a first region including a first material and a second region including a second material different from the first material.

In an embodiment, the organic inhibitor compound has a vapor pressure at 25° C. of 0.1 pascal (Pa) or less, 0.05 Pa or less, 1 Torr or less, 0.1 Torr or less, or 0.05 Torr or less.

In an embodiment, the organic inhibitor compound may include 13 or more, 14 or more, 15 or more, 18 or more, or 20 or more carbon atoms.

In an embodiment, the organic inhibitor compound may include 100 or fewer, 80 or fewer, or 60 or fewer carbon atoms.

In an embodiment, the organic inhibitor compound may include a reactive group configured to interact with the first material of the substrate. The reactive group may include a phosphonate group, an alkylsilane group, an alkoxysilane group, a chlorosilane group, a thiol group, or a combination thereof.

In an embodiment, the organic inhibitor compound may be a chlorosilane compound having an alkyl group of C14 to C30.

In an embodiment, the organic inhibitor compound may include a backbone group (for example, an unsubstituted hydrocarbon group) connected to the reactive group. The backbone group may be a hydrocarbon group including 12 or more, 15 or more, or 18 or more and 30 or fewer carbon atoms.

In an embodiment, the method may include providing the organic inhibitor compound into a container including the porous medium so that the organic inhibitor compound enters pores of the porous medium.

In an embodiment, the porous medium may have a porosity of 1% or more, or 5% or more, and 60% or less, or 50% or less.

In an embodiment, the porous medium may be a microporous material, a mesoporous material, or a macroporous material.

The porous medium may include a linear material or a three-dimensional network of the linear material, and the linear material may have a thickness of 0.1 micrometers (μm) or more, 0.5 μm or more, 1 μm or more, or 3 μm or more. The thickness may be 1000 μm or less, 500 μm or less, 100 μm or less, or 90 μm or less.

In an embodiment, the linear material may include a quartz fiber such as quartz wool, a glass fiber such as glass wool, a metal fiber such as metal wool, a heat-resistant synthetic fiber, or a combination thereof. The metal fiber may include iron, copper, stainless steel, or a combination thereof.

In an embodiment, the porous medium may include a compression-molded product of the linear material, a metal foam, a metal felt, or a combination thereof.

In an embodiment, the evaporating of the organic inhibitor compound may be performed by a thermal evaporator, for example, a vacuum thermal evaporator. The porous medium or the container including the porous medium may be heated to a predetermined temperature. The predetermined temperature may be 150° C. or more, or 200° C. or more. The predetermined temperature may be 500° C. or less, or 300° C. or less.

In an embodiment, the first chamber includes a chamber body, and the thermal evaporator may be disposed in a space defined by the chamber body. The thermal evaporator may be coupled to the chamber body (for example, so that the evaporated organic inhibitor compound may flow into the first chamber).

In an embodiment, the evaporating of the organic inhibitor compound may be performed under the first pressure. The first pressure may be 1×10⁻³ Torr or less, 1×10⁻⁴ Torr or less, or 1×10⁻⁵ Torr or less.

In an embodiment, the first material may include a dielectric, and the second material may include a metal, an organic material, or a nitride. The nitride may include silicon nitride. In an embodiment, the first material may include a metal, an organic material, or a nitride, and the second material may include a dielectric.

In an embodiment, the dielectric may include silicon oxide (for example, SiOₓ, where x is greater than 0 and equal to or less than 2), aluminum oxide (for example, Al₂Oₓ, where x is greater than 0 and equal to or less than 3), hafnium oxide (for example, HfOₓ, where x is greater than 0 and equal to or less than 2), zirconium oxide (for example, ZrOₓ, where x is greater than 0 and equal to or less than 2), or a combination thereof.

The metal may include copper (Cu), ruthenium (Ru), molybdenum (Mo), or a combination thereof.

The organic material may include amorphous carbon, a photoresist, or a combination thereof.

In an embodiment, the method may include monitoring a thickness of the self-assembled monolayer and stopping deposition when the thickness of the self-assembled monolayer reaches 50% or more, or 80% to 100%, of its maximum thickness.

In an embodiment, the predetermined time (deposition time) may be 30 seconds or more and less than 300 seconds, or 290 seconds or less.

In an embodiment, the substrate (or the first region) including the self-assembled monolayer may have a water contact angle of 102 degrees or more and 120 degrees or less.

In an embodiment, the self-assembled monolayer may have a molecular tilting angle, confirmed by a near-edge X-ray absorption fine structure (NEXAFS) analysis, of 50 degrees or less, or 45 degrees or less. The molecular tilting angle may be 30 degrees or more, or in a range of 32 degrees to 41 degrees.

In an embodiment, the method may further include performing an atomic layer deposition (ALD) on the substrate including the self-assembled monolayer (for example, on the first region) in a second chamber, to selectively deposit a thin film (or coating) on the second region (for example, a region not including the self-assembled monolayer) of the substrate.

In an embodiment, by the deposition, a substrate including the thin film (or coating), or a pattern thereof, may be obtained.

In an embodiment, the atomic layer deposition may include:
supplying a thin-film precursor gas into the second chamber; supplying an inert gas into the second chamber to purge an excess of the thin-film precursor gas; supplying a co-reactant for reaction with the thin-film precursor gas into the second chamber; and supplying an inert gas into the second chamber to purge an excess of the co-reactant.

The method may further include removing the self-assembled monolayer from the substrate.

In an embodiment, removing the self-assembled monolayer may be performed by a dry method, a wet method, or a combination thereof. The dry method may include purging with an inert gas. The wet method may involve use of an organic solvent. The wet method may include sonification, swabbing, or a combination thereof.

In an embodiment, the thin film (for example, coating) may have a predetermined thickness, for example, a thickness of about 3 nm to about 10 nm, about 4 nm to about 8 nm, about 2.5 nm to about 5 nm, or about 3 nm, and a selectivity (Selectivity) of a substrate including the thin film, calculated according to the following Equation, may be 0.8 or more:

$$selectivty ( s ) = \frac{{θ}_{GA} - {θ}_{NGA}}{{θ}_{GA} + {θ}_{NGA}}$$

Θ_{NGA}: A coating amount deposited on a first region (non-growth area: NGA); and
Θ_{GA}: a coating amount deposited on a second region (growth area: GA).

In an embodiment, the selectivity may be 0.87 or more.

In an embodiment, the thin-film precursor gas may include hafnium, strontium, titanium, barium, ruthenium, molybdenum, cobalt, copper, or a combination thereof.

In an embodiment, a substrate processing system includes a first chamber configured to perform a self-assembled monolayer (SAM) treatment, and the first chamber includes a body, a substrate holder, and a heating evaporator (for example, a vacuum heating evaporator).

The heating evaporator includes a porous medium configured to be impregnated with an organic inhibitor compound and a heating element.

The heating evaporator may be disposed inside the body or may be disposed outside the body and connected to the body.

In an embodiment, the first chamber (or the substrate holder) may further include a heater configured to heat a substrate to a desired temperature.

In an embodiment, the substrate processing system may further include a pressure-control element configured to control a pressure of an interior space of the body and, optionally, a pressure of an interior space of the heating evaporator.

The pressure-control element may be connected to the body or to the heating evaporator (for example, to an exhaust port).

In an embodiment, the heating evaporator may further include a container that accommodates the porous medium.

In an embodiment, the details regarding the porous medium are as described herein.

In an embodiment, the heating element is configured to heat the porous medium or the container including the porous medium to a predetermined temperature.

The predetermined temperature may be 150° C. or more, or 200° C. or more.

The predetermined temperature may be 500° C. or less, or 300° C. or less.

In an embodiment, the substrate processing system may further include a second chamber configured to perform an atomic layer deposition (ALD) process.

In an embodiment, the substrate processing system may further include a transfer element configured to transfer a substrate having a self-assembled monolayer formed thereon from the first chamber to the second chamber.

In an embodiment, a method of manufacturing a semiconductor device is provided.

The method includes forming a dielectric layer on a substrate and selectively depositing one or more atomic layers on the dielectric layer, wherein the step of depositing the one or more atomic layers includes the substrate processing method described herein (for example, a selective deposition method).

In an embodiment, a method of manufacturing a semiconductor device includes:
forming a transistor channel on a substrate; forming a gate dielectric layer on the transistor channel; and forming a gate electrode on the gate dielectric layer, wherein the step of forming the gate electrode includes the selective thin-film deposition method described herein.

While this disclosure has been described in connection with what is presently considered to be practical embodiments, it is to be understood that the present subject matter is not limited to the disclosed exemplary embodiments. On the contrary, it is intended to cover various modifications and equivalent arrangements included within the spirit and scope of the appended claims.

What is claimed is:

1. A method of processing a substrate, which comprises:
evaporating, under a pressure below atmospheric pressure, an organic inhibitor compound from a porous medium impregnated with the organic inhibitor compound to provide an evaporated organic inhibitor compound; and
selectively depositing the evaporated organic inhibitor compound onto a first region of a substrate under a first pressure in a first chamber containing the substrate, to form a self-assembled monolayer including the organic inhibitor compound on the first region of the substrate.

2. The method of claim 1,
wherein the substrate comprises a plurality of regions, and the plurality of regions comprise the first region including a first material and a second region including a second material different from the first material.

3. The method of claim 1,
wherein the organic inhibitor compound comprises 13 to 40 carbon atoms.

4. The method of claim 1,
wherein the organic inhibitor compound comprises a reactive group, and the reactive group comprises a phosphonate group, a thiol group, an alkylsilane group, an alkoxysilane group, a chlorosilane group, or a combination thereof.

5. The method of claim 1,
wherein the porous medium has a porosity of greater than or equal to about 1% and less than or equal to about 60%.

6. The method of claim 1,
wherein the porous medium comprises a linear material or a three-dimensional network of the linear material, and the linear material has a diameter of greater than or equal to about 0.1 micrometers and less than or equal to about 1000 micrometers.

7. The method of claim 1,
wherein the porous medium comprises glass fiber, quartz fiber, iron, copper, stainless steel, or a combination thereof.

8. The method of claim 1,
wherein the evaporating of the organic inhibitor compound is performed at a pressure of less than or equal to about 10⁻³ Torr.

9. The method of claim 1, further comprising
monitoring a thickness of the self-assembled monolayer, and
stopping deposition when the thickness reaches about 80% to about 100% of its maximum value.

10. The method of claim 1,
wherein the depositing is performed for 30 seconds or more and less than 300 seconds.

11. The method of claim 1, which comprises
wherein the substrate including the self-assembled monolayer has a water contact angle of greater than or equal to about 102° and less than or equal to about 120°; or
wherein the self-assembled monolayer has a molecular tilting angle, determined by near edge X-ray absorption fine structure analysis, that is greater than or equal to about 20° and less than or equal to about 50°.

12. The method of claim 1,
further comprising performing an atomic layer deposition on the substrate including the self-assembled monolayer in a second chamber to selectively form a thin film on a second region of the substrate that does not include the self-assembled monolayer.

13. The method of claim 1, wherein the thin film has a thickness of greater than or equal to about 3 nanometers and less than or equal to about 10 nanometers, and a selectivity obtained by the following equation is greater than or equal to about 0.8:
$$selectivty ( s ) = \frac{{θ}_{GA} - {θ}_{NGA}}{{θ}_{GA} + {θ}_{NGA}}$$
wherein
Θ_{NGA}: a coating amount deposited on a first region; and
Θ_{GA}: a coating amount deposited on a second region.

14. A substrate processing system comprising:
a first chamber configured to perform a self-assembled monolayer treatment;
wherein the first chamber comprises a body, a substrate holder, and a heating evaporator;
the heating evaporator comprises a porous medium that is configured to be impregnated with an organic inhibitor compound and a heating element; and
wherein the heating evaporator is disposed inside the body or disposed outside the body and connected to the body.

15. The substrate processing system of claim 14, wherein the porous medium has a porosity of greater than or equal to about 1% and less than or equal to about 60%.

16. The substrate processing system of claim 14,
wherein the porous medium comprises a linear material or a three-dimensional network of the linear material, and the linear material has a diameter of greater than or equal to about 0.1 micrometers and less than or equal to about 1000 micrometers.

17. The substrate processing system of claim 14,
further comprising a pressure-control element that is configured to control a pressure of an interior space of the body and, optionally, an interior space of the heating evaporator.

18. The substrate processing system of claim 14,
wherein the heating element is configured to heat the porous medium or a container including the porous medium to a predetermined temperature,
and the predetermined temperature is greater than or equal to about 150° C. and less than or equal to about 500° C.

19. The substrate processing system of claim 14,
further comprising a second chamber configured to perform an atomic layer deposition process.

20. A method of manufacturing a semiconductor device comprising:
forming a dielectric layer on a substrate; and
selectively depositing one or more atomic layers on the dielectric layer,
wherein depositing the one or more atomic layers comprises:
evaporating, under a pressure below atmospheric pressure, an organic inhibitor compound from an organic inhibitor compound-impregnated porous medium to provide an evaporated organic inhibitor compound; and
selectively depositing the evaporated organic inhibitor compound onto a first region of the substrate under a first pressure in a first chamber including the substrate, for a predetermined time, to form a self-assembled monolayer including the organic inhibitor compound on the first region of the substrate.
